(19) United States
(12) Patent Application Publication
(10) Pub. No.: US 2003/0222338 A1
(43) Pub. Date: Dec. 4, 2003

(54) Reverse wire bonding techniques

(75) Inventor: Robert F. Wallace, Sunnyvale, CA (US)

Correspondence Address: BEYER WEAVER & THOMAS LLP, P.O. BOX 778, BERKELEY, CA, 94704-0778, US

(73) Assignee: SanDisk Corporation

(21) Appl. No.: 10/039,615

(22) Filed: Jan. 4, 2002

(51) Int. Cl. H01L 23/52

(52) U.S. Cl. 257/691

(57) ABSTRACT

Thin molded semiconductor device packages that contain two semiconductor dice and techniques for forming such packages are described. The packages and techniques mainly involve reverse wirebonding the bonding wires that connect the dice to surrounding conductive contact leads. Techniques for ball bonding a first end of a bonding wire to a contact lead and a second end of the bonding wire to a semiconductor die are described. Techniques for stitch bonding a bonding wire to both a contact lead and a semiconductor die is also described.

### STATEMENT REGARDING FEDERALLY SPONSORED RESEARCH OR DEVELOPMENT

Not Applicable

### FIELD OF THE INVENTION

The present invention relates generally to semiconductor devices, and more specifically to reverse wire bonds and reverse wire-bonding techniques for use within semiconductor device packages.

### BACKGROUND OF THE INVENTION

Typically, semiconductor device packages include a semiconductor die that is electrically connected to conductive contact leads, which provide the pathway for electrical signals to travel between the die and, for example, a printed circuit board. Bonding wires are typically used to connect the die to the contact leads, and all of these various components are protected and given support by a casing of molding material. FIG. 1 illustrates a side plan, cross-sectional view of an example of a molded semiconductor device package 100 as is currently known. Device package 100 actually contains two semiconductor dice 102 and 104 that are placed back-to-back around a die attach pad 106. In this orientation, the top surfaces of each die 102 and 104 face in opposite directions. Die bond pads 108 on the top surfaces of dice 102 and 104 are connected to conductive contact leads 110 with bonding wires 112. A molding material, such as epoxy, forms a casing or a cap 114 to protect and provide support for the component parts of package 100. Cap 114 leaves the peripheral tips of leads 110 exposed so that package 100 can be connected to external electrical systems. Of note is the challenge of obtaining a relatively thin device package considering that the pair of semiconductor dice demands larger space requirements than packages containing only one die.

Semiconductor device package 100 of FIG. 1 illustrates the conventional technique of wire bonding a die to a contact lead in which bonding wires 112 are first ball bonded to die bond pads 108 of dice 102 and 104, and then stitch bonded to contact leads 110. This is typical, in part, because ball bonds 116 can be formed within a specified location with tighter tolerances than stitch bonds 118. The tighter tolerances of ball bond placement reduces the chances that bonding process will damage sensitive areas on dice 102 and 104. Unfortunately, however, the capillary tool which is typically used to extrude bonding wires 112 are raised upwardly and away from the top surface of dice 102 and 104 before drawing bonding wires 112 toward contact leads 110. The upward movement causes the bonding wires to have rather tall loops 120 that arc above the top surface of dice 102 and 104. Since molded cap 114 generally encapsulates bonding wires 112, the height of wire loops 120 directly affects the overall thickness T₁ of the molded cap 114. Unfortunately, the height of wire loops 120 force molded cap 114 to be thicker than what is desirable in today's semiconductor device applications. Wire loops 120 are especially undesirable given that package 100 already has the extra thickness of a second semiconductor die.

In view of the foregoing, a technique for reducing the overall thickness of molded semiconductor device packages would be desirable.

### BRIEF SUMMARY OF THE INVENTION

The present invention pertains to thin molded semiconductor device packages that contain two semiconductor dice and techniques for forming such packages. The techniques mainly involve reverse wirebonding the bonding wires that connect the dice to surrounding conductive contact leads. The techniques of the present invention can be applied to the various types of semiconductor packages in which wirebonding is required.

One aspect of the present invention pertains to a molded semiconductor device package that includes a first and a second semiconductor die, a contact lead, a first and a second bonding wire, and a molding cap. Each of the dice has a die bond pad and each of the dice is positioned such that the die bond pads of each die face in opposite directions. The contact lead is positioned proximate to the first and second die. The first bonding wire is ball bonded to the contact lead and stitch bonded to the die bond pad of the first die, and the second bonding wire is ball bonded to the contact lead and stitch bonded to the die bond pad of the second die. The molding cap encapsulates the first and second die, the first and second bonding wire, and a portion of the contact lead. In another aspect of the present invention, a ball of conductive material is formed on each of the die bond pads and then the stitch bonds are made on top of the conductive balls. In another aspect, the bonding wires are formed of aluminum and the wires are stitch bonded to both the contact lead and the semiconductor dice.

The present invention also includes methods for forming the semiconductor devices described above.

These and other features and advantages of the present invention will be presented in more detail in the following specification of the invention and the accompanying figures, which illustrate by way of example the principles of the invention.

### BRIEF DESCRIPTION OF THE DRAWINGS

The invention, together with further advantages thereof, may best be understood by reference to the following description taken in conjunction with the accompanying drawings in which:

FIG. 1 illustrates a side plan, cross-sectional view of an example of a molded semiconductor device package as is currently known.

FIG. 2 illustrates side plan, cross-sectional view of a molded semiconductor device package, according to one embodiment of the present invention.

FIGS. 3 and 4 illustrate the stages of forming a semiconductor device package according to an alternative method of reverse wire bonding.

FIG. 5 illustrates a side plan, cross-sectional view of the internal components of a semiconductor device according to an alternative embodiment of the present invention.

### DETAILED DESCRIPTION OF THE INVENTION

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known operations have not been described in detail so not to unnecessarily obscure the present invention.

The present invention pertains to thin molded semiconductor device packages that contain two semiconductor dice and techniques for forming such packages. The technique involves reverse wirebonding the bonding wires that connect the dice to surrounding conductive contact leads. The techniques of the present invention can be applied to the various types of semiconductor packages in which wirebonding is required. For instance, the technique can be applied to molded plastic packages such as, but not limited to, thin small outline packages (TSOP), quad flat packages (QFP) and leadless leadframe packages (LLP).

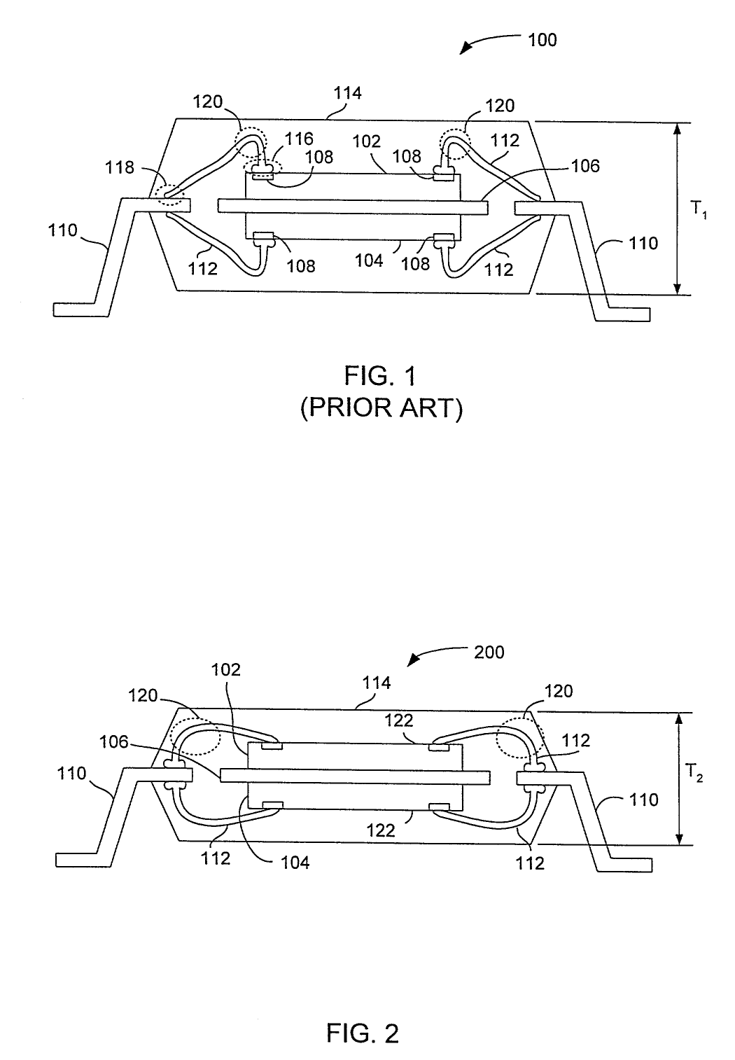

FIG. 2 illustrates side plan, cross-sectional view of a molded semiconductor device package 200, according to one embodiment of the present invention. Semiconductor device package 200 includes a molding cap 114 and conductive contact leads 110, which extend outside of cap 114. Within molding cap 114 are contained the conductive dice 102 and 104, die attach pad 106, and bonding wires 112. The bonding wires 112 are bonded to the bonding pads and contact leads 110 in a “reverse” manner with respect to the conventional technique shown in FIG. 1. Specifically, bonding wires 112 are ball bonded to contact leads 110 and stitch bonded to die bond pads 108 of semiconductor dice 102 and 104. Since the ball bonds 116 on the contact leads 110 are positioned in between each of die 102 and 104 and are in a lower orientation with respect to the top surfaces 122 of each die 102 and 104, wire loops 120 do not extend excessively above each of the dice. The positioning of the wire loops 120 allow molded cap 114 to be formed with a smaller thickness, T₂, than is conventionally obtainable. Specific embodiments of device package 200 can have a thickness, T₂ that is less than 1 millimeter. For instance, device package 200 can be formed to have a thickness of 0.7 millimeters.

Reverse wire bonding can be implemented to connect various components for the purpose of reducing the overall thickness of an electronic device wherein one contact point is relatively lower than the other contact point. The thinner device is obtained because the loop of the bonding wire caused by the ball bonding process does not extend excessively above the higher of the contact points. For instance, two semiconductor dice that are at different height levels can also be connected by reverse wire bonds.

Each of bonding wires 112 are first ball bonded to a contact lead 110 and thereafter stitch bonded to a die bond pad 108 of one of the dice. Bonding wires 110 are either ball bonded to the top or bottom surface of contact leads 110 depending upon which die, 102 or 104, a specific bonding wire 112 is connected to. Specifically, bonding wires 112 are ball bonded to the top surface of a contact lead 110 if it is to be stitch bonded to the top die 102 and are ball bonded to the bottom surface of a contact lead 110 if it is to be stitch bonded to the bottom die 104. The bonding process can be performed simultaneously for each of the die bond pads or they can be formed one at a time. Bonding wires 112 can be formed of gold, however, other conductive materials such as copper and aluminum can also be used.

Each of the dice 102 and 104 can contain integrated circuits to form various electrical components. For instance, each of the dice can contain memory or logic units.

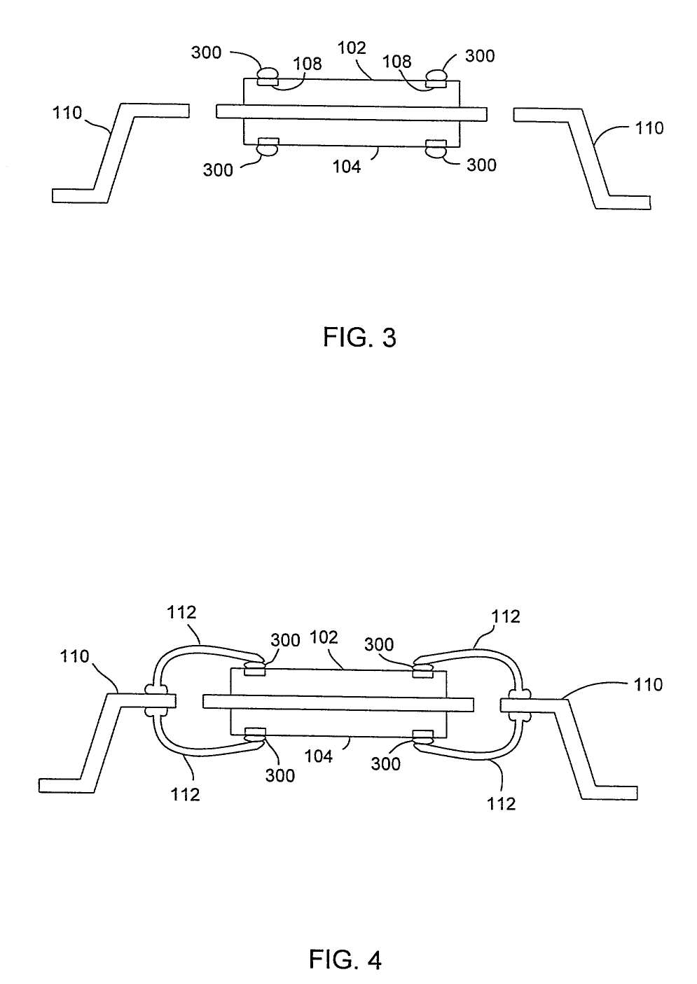

FIGS. 3 and 4 illustrate the stages of forming a semiconductor device package according to an alternative method of reverse wire bonding. The method described by FIGS. 3 and 4 involves forming a conductive ball formation on each of the die bond pads (FIG. 3) and then forming the stitch bond on top of the conductive ball formation (FIG. 4).

FIG. 3 illustrates a side plan cross-sectional view of the semiconductor device package 200 before bonding wires are attached and a molding cap is formed. Conductive material 300 is formed on top of each die bond pad 108. Conductive material 300 can take the shape of a ball, a bump, or any other various shapes. For purposes describing the invention, conductive material 300 will be referred to as conductive ball 300 hereinafter. Conductive ball 300 can be formed by using the same ball bonding technique that is used to form the ball bonds described in this disclosure. This is accomplished by forming a ball bond on the die bond pads 108 and then disconnecting the wire from the ball so that only a ball 300 is left on the die bond pads 108. Conductive balls 300 can be formed in alternative manners. For example, conductive balls 300 can also be deposited or screen-printed onto the die bond pads 108. Conductive balls 300 can be formed of the same material as the bonding wires, or they can be formed of different conductive materials. Selection of such material composition depends upon specific package design requirements. The conductive balls 300 provide a stand-off distance between the capillary tool used to form stitch bond such that the tool will be less likely to come into damaging contact with semiconductor dice 102 and 104.

FIG. 4 shows that the reverse wire bonding is completed by ball bonding bonding wires 112 to contact leads 110, then stitch bonding the opposite ends of each of the bonding wires 112 to conductive balls 300. The stitch bonding process tends to compress the ball 300 into a flatter shape. After the wirebonding process, a molding cap can be injection molded to encapsulate the semiconductor device components.

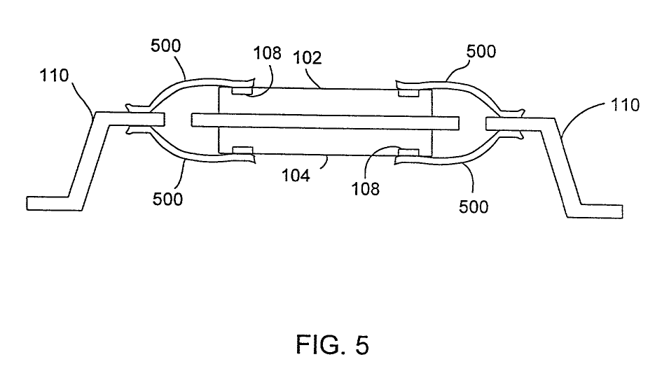

FIG. 5 illustrates a side plan, cross-sectional view of the internal components of a semiconductor device according to an alternative embodiment of the present invention. Specifically, FIG. 5 shows bonding wires 500 that are stitch bonded to both the conductive contact leads 110 and die bond pads 108 of die 102 and 104. The configuration of FIG. 5 can be formed by first stitch bonding a wire to a contact lead and then, subsequently, to die bond pad 108 of one of dice 102 or 104. Stitch bonding processes typically result in a higher arcing wire loop near the first formed stitch bond, therefore, by first stitch bonding to the relatively lower contact leads, the height of bonding wires 500 over dice 102 and 104 can be minimized. However, considering that the wire loops of stitch bonds are smaller than the loops of ball bonding techniques, a semiconductor device package containing bonding wires that were first stitch bonded to the die bond pads 108 and then stitch bonded to contact leads 110 can also have a relatively small thickness.

Bonding wires 500 are formed of aluminum, however, the wire can be formed of other materials in alternative embodiments. For instance, bonding wires 500 could also be formed of gold or copper.

In an alternative embodiment of the device of FIG. 5, conductive ball formations can be formed on the die bond pads 108 such that bonding wires 500 are stitch bonded on top of the conductive balls.

While this invention has been described in terms of several preferred embodiments, there are alteration, permutations, and equivalents, which fall within the scope of this invention. It should also be noted that there are many alternative ways of implementing the methods and apparatuses of the present invention. It is therefore intended that the following appended claims be interpreted as including all such alterations, permutations, and equivalents as fall within the true spirit and scope of the present invention.

We claim:

1. A molded semiconductor device package comprising:
a die attach pad;
a first and a second semiconductor die, each die having a die bond pad, each of the die positioned such that the die bond pads of each die face in opposite directions, the first and second die being connected to opposing surfaces of the die attach pad;
a contact lead positioned proximate to the first and second die;
a first bonding wire that is stitch bonded to the die bond pad of the first die;
a second bonding wire that is stitch bonded to the die bond pad of the second die; and
a molding cap that encapsulates the first and second die, the first and second bonding wire, and a portion of the contact lead, wherein the molding cap has a thickness of less than about 1 millimeter.

2. A molded semiconductor device package as recited in claim 1 further comprising:
a first conductive ball formation that is formed between the first bonding wire and the die bond pad of the first die; and
a second conductive ball formation that is formed between the second bonding wire and the die bond pad of the second die.

3. A molded semiconductor device package as recited in claim 1 wherein the first bonding wire is also ball bonded to the contact lead and the second bonding wire is also ball bonded to the contact lead.

4. A molded semiconductor device package as recited in claim 1 wherein the first bonding wire is also stitch bonded to the contact lead and the second bonding wire is also stitch bonded to the contact lead.

5. A molded semiconductor device package as recited in claim 1 wherein the first and second bonding wire are formed of a material selected from the group consisting of gold, copper and aluminum.

6. A molded semiconductor device package as recited in claim 1 wherein the package is either a thin small outline package or a quad flat pack package.

7. A molded semiconductor device package comprising:
a die attach pad;
a first and a second semiconductor die, each die having a die bond pad, each of the die positioned such that the die bond pads of each die face in opposite directions, the first and second die being connected to opposing surfaces of the die attach pad;
a contact lead positioned proximate to the first and second die;
a first bonding wire that is ball bonded to the contact lead and stitch bonded to the die bond pad of the first die;
a second bonding wire that is ball bonded to the contact lead and stitch bonded to the die bond pad of the second die; and
a molding cap that encapsulates the first and second die, the first and second bonding wire, and a portion of the contact lead.

8. A molded semiconductor device package as recited in claim 7 wherein the package is either a thin small outline package or a quad flat pack package.

9. A molded semiconductor device package as recited in claim 7 wherein the first and second bonding wire are formed of a material selected from the group consisting of gold, copper and aluminum.

10. A molded semiconductor device package as recited in claim 7 wherein the molding cap has a thickness of less than about 1 millimeter.

11. A molded semiconductor device package as recited in claim 7 wherein the first die contains integrated circuit components configured to form a memory or a logic unit.

12. A molded semiconductor device package comprising:
a pair of semiconductor dice that are oriented such that a top surface of each die are facing in opposite directions, the top surface of each die having at least one die bond pad;
a conductive ball formation positioned on the die bond pad;
at least one contact lead positioned proximate to the pair of semiconductor dice;
at least one bonding wire that is ball bonded to the contact lead and stitch bonded to the conductive ball formation; and
a molding cap that encapsulates the pair of semiconductor dice, the conductive ball formation, the bonding wire and a portion of the contact lead.

13. A molded semiconductor device package as recited in claim 12 further comprising:
a die attach pad that is attached to and sandwiched between the pair of semiconductor dice.

14. A molded semiconductor device package as recited in claim 12 wherein the bonding wire is gold.

15. A molded semiconductor device package as recited in claim 12 wherein the molding cap has a thickness of less than about 1 millimeter in thickness.

16. A molded semiconductor device package comprising:
a die attach pad;
a first and a second semiconductor die, each die having a die bond pad, each of the die positioned such that the die bond pads of each die face in opposite directions, the first and second die being connected to opposing surfaces of the die attach pad;
a contact lead positioned proximate to the first and second die;
a first aluminum bonding wire that is stitch bonded to the contact lead and stitch bonded to the die bond pad of the first die, wherein the first aluminum bonding wire was stitch bonded to the contact lead before being stitch bonded to the die bond pad;
a second aluminum bonding wire that is stitch bonded to the contact lead and stitch bonded to the die bond pad of the second die, wherein the second aluminum bonding wire was stitch bonded to the contact lead before being stitch bonded to the die bond pad; and
a molding cap that encapsulates the first and second die, the first and second bonding wire, and a portion of the contact lead.

17. A molded semiconductor device package as recited in claim 16 wherein the package is either a thin small outline package or a quad flat pack package.

18. A molded semiconductor device package as recited in claim 16 wherein the molding cap has a thickness of less than about 1 millimeter.

19. A molded semiconductor device package as recited in claim 16 wherein the first die contains integrated circuit components configured to form a memory or a logic unit.

20. A method for forming electrical connections on a semiconductor device that includes a first and a second semiconductor die, each die having a die bond pad, each of the die positioned such that the die bond pads of each die face in opposite directions, and a contact lead positioned proximate to the first and second die, the method comprising:
(a) forming a first electrically conductive bump on the die bond pad of the first semiconductor die;
(b) ball bonding a free end of a first bonding wire to the contact lead, and then stitch bonding the opposite end of the first bonding wire to the first electrically conductive bump on the die bond pad of the first semiconductor die;
(c) forming a second electrically conductive bump on the die bond pad of the second semiconductor die; and
(d) ball bonding a free end of a second bonding wire to the contact lead, and then stitch bonding the opposite end of the second bonding wire to the second electrically conductive bump on the die bond pad of the second semiconductor die.

21. A method as recited in claim 20 further comprising:
encapsulating the first and second semiconductor die, the first and second bonding wires and a portion of the contact lead within a molding material.

22. A method as recited in claim 20 wherein the first and second bonding wires are formed of gold.

23. A method for forming electrical connections on a semiconductor device that includes a first and a second semiconductor die, each die having a die bond pad, each of the die positioned such that the die bond pads of each die face in opposite directions, and a contact lead positioned proximate to the first and second die, the method comprising:
(a) ball bonding a free end of a first bonding wire to the contact lead, and then stitch bonding the opposite end of the first bonding wire to the die bond pad of the first semiconductor die; and
(b) ball bonding a free end of a second bonding wire to the contact lead, and then stitch bonding the opposite end of the second bonding wire to the die bond pad of the second semiconductor die.

24. A method for forming electrical connections on a semiconductor device that includes a first and a second semiconductor die; each die having a die bond pad, each of the die positioned such that the die bond pads of each die face in opposite directions, and a contact lead positioned proximate to the first and second die, the method comprising:
(a) stitch bonding a free end of a first aluminum bonding wire to the contact lead, and then stitch bonding the opposite end of the first aluminum bonding wire to the die bond pad of the first semiconductor die; and
(b) stitch bonding a free end of a second aluminum bonding wire to the contact lead, and then stitch bonding the opposite end of the second aluminum bonding wire to the die bond pad of the second semiconductor die.

25. A method as recited in claim 24 further comprising:
encapsulating the first and second semiconductor die, the first and second bonding wires and a portion of the contact lead within a molding material.
